(19) United States
(12) Patent Application Publication
(10) Pub. No.: US 2026/0247889 A1
(43) Pub. Date: Aug. 20, 2026

(54) PROCESSING METHOD, METHOD OF MANUFACTURING SEMICONDUCTOR DEVICE, PROCESSING APPARATUS, AND RECORDING MEDIUM

(71) Applicant: KOKUSAI ELECTRIC CORPORATION, Tokyo (JP)

(72) Inventor: Ryuji YAMAMOTO, Tokyo (JP)

(73) Assignee: KOKUSAI ELECTRIC CORPORATION, Tokyo (JP)

(21) Appl. No.: 19/425,132

(22) Filed: Dec. 18, 2025

(30) Foreign Application Priority Data
Jan. 16, 2025 (JP) 2025-005894

(51) Int. Cl. H10P 50/64; H10P 72/00; H10P 72/10; H10P 72/30

(52) U.S. Cl. CPC H10P 50/642; H10P 72/0466; H10P 72/12; H10P 72/3412

(57) ABSTRACT

There is provided a technique that includes: (a) preparing a first process container in which a substance X-containing layer is formed; (b) loading a substrate into the first process container in which the substance X-containing layer is formed; and (c) supplying a first processing agent to the substrate in the first process container in which the substance X-containing layer is formed, such that the first processing agent reacts with a substance X derived from the substance X-containing layer, thereby etching a surface of the substrate.

### CROSS-REFERENCE TO RELATED APPLICATION

This application is based upon and claims the benefit of priority from Japanese Patent Application No. 2025-005894, filed on Jan. 16, 2025, the entire contents of which are incorporated herein by reference.

### TECHNICAL FIELD

The present disclosure relates to a processing method, a method of manufacturing a semiconductor device, a processing apparatus, and a recording medium.

### BACKGROUND

In the related art, as a process of manufacturing a semiconductor device, a process of etching a surface of a substrate may be often carried out.

### SUMMARY

Some embodiments of the present disclosure provide a technique capable of efficiently etching a surface of a substrate.

According to some embodiments of the present disclosure, there is provided a technique, which includes: (a) preparing a first process container in which a substance X-containing layer is formed; (b) loading a substrate into the first process container in which the substance X-containing layer is formed; and (c) supplying a first processing agent to the substrate in the first process container in which the substance X-containing layer is formed, such that the first processing agent reacts with a substance X derived from the substance X-containing layer, thereby etching a surface of the substrate.

### BRIEF DESCRIPTION OF DRAWINGS

The accompanying drawings, which are incorporated in and constitute a part of the specification, illustrate embodiments of the present disclosure.

FIG. 1 is a schematic configuration view of a vertical process furnace of a processing apparatus suitably used in a first embodiment of the present disclosure, in which a portion of the process furnace is shown in a vertical cross section.

FIG. 2 is a schematic configuration view of the vertical process furnace of the processing apparatus suitably used in the first embodiment of the present disclosure, in which a portion of the process furnace is shown in a cross section taken along line A-A in FIG. 1.

FIG. 3 is a schematic configuration diagram of a controller of the processing apparatus suitably used in the first embodiment of the present disclosure, in which a control system of the controller is shown in a block diagram.

FIG. 4A is a partial cross-sectional schematic view of a processing apparatus according to the first embodiment of the present disclosure, showing a state before a substrate with an oxide formed on its surface is loaded into a first process container in which a substance X-containing layer is formed. FIG. 4B is a partial cross-sectional schematic view of the processing apparatus according to the first embodiment of the present disclosure, showing a state after the substrate is loaded into the first process container. FIG. 4C is a partial cross-sectional schematic view of the processing apparatus according to the first embodiment of the present disclosure, showing a state in which a first processing agent is supplied to the substrate in the first process container to etch the surface of the substrate. FIG. 4D is a partial cross-sectional schematic view of the processing apparatus according to the first embodiment of the present disclosure, showing a state after the etching of the surface of the substrate is completed. FIG. 4E is a partial cross-sectional schematic view of the processing apparatus according to the first embodiment of the present disclosure, showing a state in which a second processing agent is supplied to the substrate in the first process container to form a film on the substrate with the surface etched.

FIG. 5A is a partial cross-sectional schematic view of a processing apparatus according to a second embodiment of the present disclosure, showing a state before a first boat supporting substrates with oxides formed on their surfaces is loaded into a first process container in which a substance X-containing layer is formed. FIG. 5B is a partial cross-sectional schematic view of the processing apparatus according to the second embodiment of the present disclosure, showing a state when a first processing agent is supplied to the substrates on the first boat loaded into the first process container to etch the surfaces of the substrates. FIG. 5C is a partial cross-sectional schematic view of the processing apparatus according to the second embodiment of the present disclosure, showing a state after the first boat supporting the substrates with the surfaces etched is unloaded from the first process container, but before the first boat is loaded into a second process container, and before a second boat supporting substrates with oxides formed on their surfaces is loaded into the first process container. FIG. 5D is a partial cross-sectional schematic view of the processing apparatus according to the second embodiment of the present disclosure, showing a state in which a process of supplying a second processing agent to the substrates on the first boat loaded into the second process container to form a film on the substrates with the surfaces etched and a process of supplying the first processing agent to the substrates on the second boat loaded into the first process container to etch the surfaces of the substrates are performed in parallel.

FIG. 6 is a flow diagram according to the second embodiment of the present disclosure, showing a state in which steps A to D are performed a plurality of times, and the step D for an n-th time and at least one selected from the group of the steps A to C for an (n+1)-th time are performed in parallel.

FIG. 7A is a partial cross-sectional schematic view of a processing apparatus according to a third embodiment of the present disclosure, showing an example in which at least one selected from the group of a content of a substance X in the substance X-containing layer, a concentration of the substance X in the substance X-containing layer, a density of the substance X in the substance X-containing layer, and a thickness of the substance X-containing layer is different between an upper portion and other portions (middle and lower portions) within the first process container. FIG. 7B is a partial cross-sectional schematic view of the processing apparatus according to the third embodiment of the present disclosure, showing another example in which at least one selected from the group of a content of the substance X in the substance X-containing layer, a concentration of the substance X in the substance X-containing layer, a density of the substance X in the substance X-containing layer, and a thickness of the substance X-containing layer is different between a middle portion and other portions (upper and lower portions) within the first process container. FIG. 7C is a partial cross-sectional schematic view of the processing apparatus according to the third embodiment of the present disclosure, showing another example in which at least one selected from the group of a content of the substance X in the substance X-containing layer, a concentration of the substance X in the substance X-containing layer, a density of the substance X in the substance X-containing layer, and a thickness of the substance X-containing layer is different between a lower portion and other portions (upper and middle portions) within the first process container.

FIG. 8A is a partial cross-sectional schematic view showing one configuration example of a process furnace included in the processing apparatus according to the third embodiment of the present disclosure. FIG. 8B is a partial cross-sectional schematic view showing another configuration example of the process furnace included in the processing apparatus according to the third embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment of the Present Disclosure

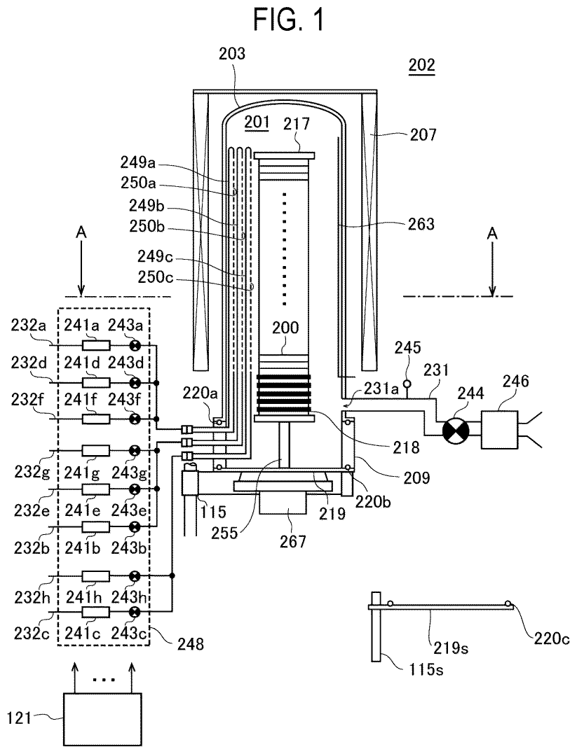

A first embodiment of the present disclosure will now be described mainly with reference to FIGS. 1 to 3 and 4A to 4E. The drawings used in the following description are schematic, and dimensional relationships, ratios, and the like of various elements shown in the drawings may not match actual ones. Further, dimensional relationships, ratios, and the like of various elements among plural figures may not match each other.

### (1) Configuration of Processing Apparatus

As shown in FIG. 1, a process furnace 202 of a processing apparatus includes a heater 207 as a temperature regulator (a heating part). The heater 207 is formed in a cylindrical shape and is supported by a support plate so as to be vertically installed. The heater 207 functions as an activator5 (an exciter) configured to thermally activate (excite) a gas.

A reaction tube 203 is disposed inside the heater 207 to be concentric with the heater 207. The reaction tube 203 is made of, for example, a heat resistant material such as quartz (SiO₂) or silicon carbide (SiC), and is formed in a cylindrical shape with its upper end closed and its lower end opened. A manifold 209 is disposed to be concentric with the reaction tube 203 under the reaction tube 203. The manifold 209 is constituted by, for example, a metal material such as stainless steel (SUS), and formed in a cylindrical shape with both of its upper and lower ends opened. The upper end of the manifold 209 engages with the lower end of the reaction tube 203 so as to support the reaction tube 203. An O-ring 220a serving as a seal is provided between the manifold 209 and the reaction tube 203. Similar to the heater 207, the reaction tube 203 is vertically installed. A process container (reaction container) mainly includes the reaction tube 203 and the manifold 209. A process chamber 201 is formed in a hollow cylindrical area of the process container. The process chamber 201 is configured to be capable of accommodating a plurality of wafers 200 as substrates. Processing on the wafers 200 is performed in the process chamber 201.

Nozzles 249a to 249c as first to third suppliers are installed in the process chamber 201 so as to penetrate a sidewall of the manifold 209. The nozzles 249a to 249c are also referred to as first to third nozzles, respectively. The nozzles 249a to 249c are made of, for example, a heat resistant material such as quartz or SiC. Gas supply pipes 232a to 232c are connected to the nozzles 249a to 249c, respectively. The nozzles 249a to 249c are different nozzles, and each of the nozzles 249a and 249c is installed adjacent to the nozzle 249b.

Mass flow controllers (MFCs) 241a to 241c, which are flow rate controllers (flow rate control parts), and valves 243a to 243c, which are opening/closing valves, are installed at the gas supply pipes 232a to 232c, respectively, sequentially from the upstream side of gas flow. Each of gas supply pipes 232d and 232f is connected to the gas supply pipe 232a at the downstream side of the valves 243a. Each of gas supply pipes 232e and 232g is connected to the gas supply pipe 232b at the downstream side of the valves 243b. A gas supply pipe 232h is connected to the gas supply pipe 232c at the downstream side of the valves 243c. MFCs 241d to 241h and valves 243d to 243h are installed at the gas supply pipes 232d to 232h, respectively, sequentially from the upstream side of gas flow. The gas supply pipes 232a to 232h are made of, for example, a metal material such as SUS.

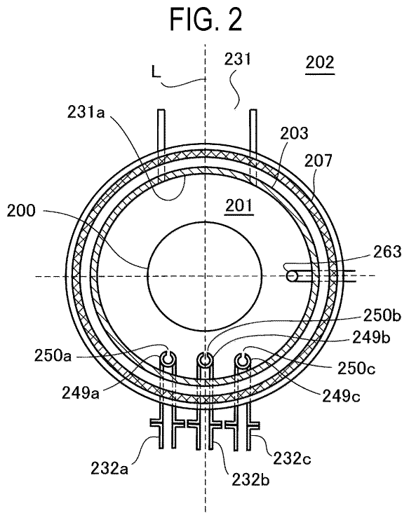

As shown in FIG. 2, each of the nozzles 249a to 249c is installed in an annular space (in plan view) between an inner wall of the reaction tube 203 and the wafers 200 so as to extend upward from a lower side to an upper side of the inner wall of the reaction tube 203, that is, along an arrangement direction of the wafers 200. Specifically, each of the nozzles 249a to 249c is installed in a region horizontally surrounding a wafer arrangement region in which the wafers 200 are arranged at a lateral side of the wafer arrangement region, along the wafer arrangement region. In plan view, the nozzle 249b is disposed so as to face an exhaust port 231a to be described later on a straight line with centers of the wafers 200 in the process chamber 201 interposed therebetween. The nozzles 249a and 249c are arranged with a straight line L passing through the nozzle 249b and the center of the exhaust port 231a interposed therebetween along the inner wall of the reaction tube 203 (an outer peripheral portion of the wafers 200). The straight line L is also a straight line passing through the nozzle 249b and the centers of the wafers 200. That is, it can be said that the nozzle 249c is installed on the side opposite to the nozzle 249a with the straight line L interposed therebetween. The nozzles 249a and 249c are arranged in line symmetry with the straight line L as an axis of symmetry. Gas supply holes 250a to 250c configured to supply a gas are formed on side surfaces of the nozzles 249a to 249c, respectively. Each of the gas supply holes 250a to 250c is opened so as to oppose (face) the exhaust port 231a in plan view, which enables a gas to be supplied toward the wafers 200. A plurality of gas supply holes 250a to 250c are formed from the lower side to the upper side of the reaction tube 203.

A fluorine (F)-containing substance is supplied from the gas supply pipe 232a into the process chamber 201 via the MFC 241a, the valve 243a, and the nozzle 249a. The F-containing substance is used as an etching agent as a first processing agent.

A precursor is supplied from the gas supply pipe 232b into the process chamber 201 via the MFC 241b, the valve 243b, and the nozzle 249b. The precursor is used as a film-forming agent as a second processing agent. The precursor is also used as a pre-coating agent.

A catalyst is supplied from the gas supply pipe 232c into the process chamber 201 via the MFC 241c, the valve 243c, and the nozzle 249c. The catalyst is used as a pre-coating agent.

A substance X is supplied from the gas supply pipe 232d into the process chamber 201 via the MFC 241d, the valve 243d, the gas supply pipe 232a, and the nozzle 249a. The substance X is used as a pre-coating agent.

A reducing agent is supplied from the gas supply pipe 232e into the process chamber 201 via the MFC 241e, the valve 243e, the gas supply pipe 232b, and the nozzle 249b.

An inert gas is supplied from the gas supply pipes 232f to 232h into the process chamber 201 via the MFCs 241f to 241h, the valves 243f to 243h, the gas supply pipes 232a to 232c, and the nozzles 249a to 249c, respectively. The inert gas acts as a purge gas, a carrier gas, a dilution gas, or the like.

A F-containing substance supply system mainly includes the gas supply pipe 232a, the MFC 241a, and the valve 243a. A precursor supply system mainly includes the gas supply pipe 232b, the MFC 241b, and the valve 243b. A catalyst supply system mainly includes the gas supply pipe 232c, the MFC 241c, and the valve 243c. A substance X supply system mainly includes the gas supply pipe 232d, the MFC 241d, and the valve 243d. A reducing agent supply system mainly includes the gas supply pipe 232e, the MFC 241e, and the valve 243e. An inert gas supply system mainly includes the gas supply pipes 232f to 232h, the MFCs 241f to 241h, and the valves 243f to 243h. The F-containing substance supply system is also referred to as a first processing agent supply system (an etching agent supply system). The precursor supply system is also referred to as a second processing agent supply system (a film-forming agent supply system). Each, some or the entirety of the precursor supply system, the catalyst supply system, and the substance X supply system is also referred to as a pre-coating agent supply system. The inert gas supply system is also be referred to as a purge gas supply system.

One or the entirety of the above-described various supply systems may be constituted as an integrated supply system 248 in which the valves 243a to 243h, the MFCs 241a to 241h, and so on are integrated. The integrated supply system 248 is connected to each of the gas supply pipes 232a to 232h. In addition, the integrated supply system 248 is configured such that operations of supplying various substances (various gases) into the gas supply pipes 232a to 232h, that is, opening/closing operations of the valves 243a to 243h, flow rate regulating operations by the MFCs 241a to 241h, and the like are controlled by a controller 121 which will be described later. The integrated supply system 248 is constituted as an integral or detachable integrated unit, and may be attached to or detached from the gas supply pipes 232a to 232h and the like on an integrated unit basis, such that maintenance, replacement, extension, and the like of the integrated supply system 248 may be performed on an integrated unit basis.

The exhaust port 231a configured to exhaust an internal atmosphere of the process chamber 201 is installed below the sidewall of the reaction tube 203. As shown in FIG. 2, in plan view, the exhaust port 231a is installed at a position opposing (facing) the nozzles 249a to 249c (the gas supply holes 250a to 250c) with the wafers 200 interposed therebetween. The exhaust port 231a may be installed from the lower side to the upper side of the sidewall of the reaction tube 203, that is, along the wafer arrangement region. An exhaust pipe 231 is connected to the exhaust port 231a. A vacuum pump 246 as a vacuum exhauster is connected to the exhaust pipe 231 via a pressure sensor 245, which is a pressure detector (a pressure detection part) configured to detect an internal pressure of the process chamber 201, and an auto pressure controller (APC) valve 244, which is a pressure regulator (a pressure regulating part). The APC valve 244 is configured to be capable of performing or stopping a vacuum exhausting operation in the process chamber 201 by opening or closing the valve while the vacuum pump 246 is actuated, and is also configured to be capable of regulating the internal pressure of the process chamber 201 by adjusting a degree of valve opening based on pressure information detected by the pressure sensor 245 while the vacuum pump 246 is actuated. An exhaust system mainly includes the exhaust pipe 231, the APC valve 244, and the pressure sensor 245. The exhaust system may include the vacuum pump 246.

A seal cap 219, which serves as a furnace opening lid configured to be capable of hermetically sealing a lower end opening of the manifold 209, is installed under the manifold 209. The seal cap 219 is made of, for example, a metal material such as SUS, and is formed in a disc shape. An O-ring 220b, which is a seal making contact with the lower end of the manifold 209, is installed on an upper surface of the seal cap 219. A rotator 267 configured to rotate a boat 217, which will be described later, is installed under the seal cap 219. A rotary shaft 255 of the rotator 267 is connected to the boat 217 through the seal cap 219. The rotator 267 is configured to rotate the wafers 200 by rotating the boat 217. The seal cap 219 is configured to be vertically moved up or down by a boat elevator 115 which is an elevator installed outside the reaction tube 203. The boat elevator 115 is constituted as a transporter (transport mechanism) configured to load or unload (transport) the wafers 200 into or out of the process chamber 201 by moving the seal cap 219 up or down.

A shutter 219s, which serves as a furnace opening lid configured to be capable of hermetically sealing a lower end opening of the manifold 209 in a state where the seal cap 219 is lowered and the boat 217 is unloaded from the process chamber 201, is installed under the manifold 209. The shutter 219s is made of, for example, a metal material such as SUS, and is formed in a disc shape. An O-ring 220c, which is a seal making contact with the lower end of the manifold 209, is installed on an upper surface of the shutter 219s. The opening/closing operation (such as elevation operation, rotation operation, or the like) of the shutter 219s is controlled by a shutter opening/closing mechanism 115s.

The boat 217 serving as a substrate support is configured to support a plurality of wafers 200, for example, 25 to 200 wafers, in such a state that the wafers 200 are arranged in a horizontal posture and in multiple stages along a vertical direction with the centers of the wafers 200 aligned with one another. That is, the boat 217 is configured to arrange the wafers 200 to be spaced apart from each other. The boat 217 is made of, for example, a heat resistant material such as quartz or SiC. Heat insulating plates 218 made of, for example, a heat resistant material such as quartz or SiC are installed below the boat 217 in multiple stages.

A temperature sensor 263 serving as a temperature detector is installed in the reaction tube 203. Based on temperature information detected by the temperature sensor 263, a state of supplying electric power to the heater 207 is regulated such that a temperature distribution inside the process chamber 201 becomes a desired temperature distribution. The temperature sensor 263 is installed along the inner wall of the reaction tube 203.

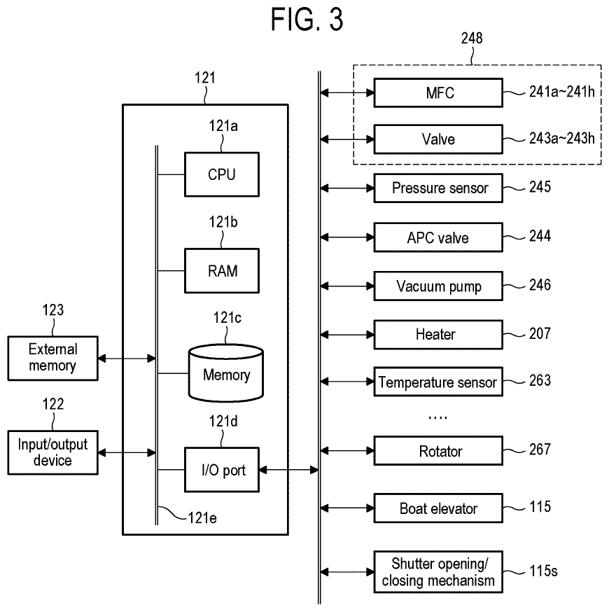

As shown in FIG. 3, a controller 121, which is a control part (control means or unit), is constituted as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 122 including, e.g., a touch panel or the like, is connected to the controller 121. Further, an external memory 123 may be connected to the controller 121. Further, the processing apparatus may be configured to include one controller, or may be configured to include a plurality of controllers. That is, control to perform a processing sequence to be described later may be performed by using one controller, or may be performed by using a plurality of controllers. Further, the plurality of controller may be constituted as a control system in which the plurality of controllers are connected to each other via a wired or wireless communication network, and the entire control system may perform control to perform the processing sequence to be described later. When the term “controller” is used in the present disclosure, it may include one controller, a plurality of controllers, or a control system constituted by a plurality of controllers.

The memory 121c is constituted by, for example, a flash memory, a hard disk drive (HDD), a solid state drive (SSD), or the like. A control program to control operations of a processing apparatus, a process recipe in which sequences and conditions of substrate processing to be described later are written, etc. are readably recorded and stored in the memory 121c. The process recipe functions as a program combined to cause, by the controller 121, the processing apparatus to execute each sequence in the substrate processing, which will be described later, to obtain an expected result. Hereinafter, the process recipe and the control program may be generally and simply referred to as a “program (program product).” Furthermore, the process recipe may be simply referred to as a “recipe.” When the term “program” is used herein, it may indicate a case of including the recipe, a case of including the control program, or a case of including both the recipe and the control program. The RAM 121b is configured as a memory area (work area) in which programs or data read by the CPU 121a are temporarily stored.

The I/O port 121d is connected to the MFCs 241a to 241h, the valves 243a to 243h, the pressure sensor 245, the APC valve 244, the vacuum pump 246, the temperature sensor 263, the heater 207, the rotator 267, the boat elevator 115, the shutter opening/closing mechanism 115s, and so on.

The CPU 121a is configured to be capable of reading and executing the control program from the memory 121c. The CPU 121a is also configured to be capable of reading the recipe from the memory 121c according to an input of an operation command from the input/output device 122. The CPU 121a is configured to be capable of controlling flow rate regulating operations of various kinds of substances (gases) by the MFCs 241a to 241h, opening/closing operations of the valves 243a to 243h, an opening/closing operation of the APC valve 244, an pressure regulating operation performed by the APC valve 244 based on the pressure sensor 245, actuating and stopping operations of the vacuum pump 246, a temperature regulating operation performed by the heater 207 based on the temperature sensor 263, operations of rotating the boat 217 and adjusting a rotation speed of the boat 217 with the rotator 267, an operation of moving the boat 217 up or down by the boat elevator 115, an opening/closing operation of the shutter 219s by the shutter opening/closing mechanism 115s, and so on, according to contents of the read recipe.

The controller 121 may be constituted by installing, on the computer, the aforementioned program recorded and stored in the external memory 123. Examples of the external memory 123 may include a magnetic disk such as a HDD, an optical disc such as a CD, a semiconductor memory such as a USB memory or a SSD, and the like. The memory 121c or the external memory 123 is constituted as a computer-readable recording medium. Hereinafter, the memory 121c and the external memory 123 may be generally and simply referred to as a “recording medium.” When the term “recording medium” is used herein, it may indicate a case of including the memory 121c, a case of including the external memory 123, or a case of including both the memory 121c and the external memory 123. Furthermore, the program may be provided to the computer by using communication means or unit such as the Internet or a dedicated line, instead of using the external memory 123.

### (2) Processing Process

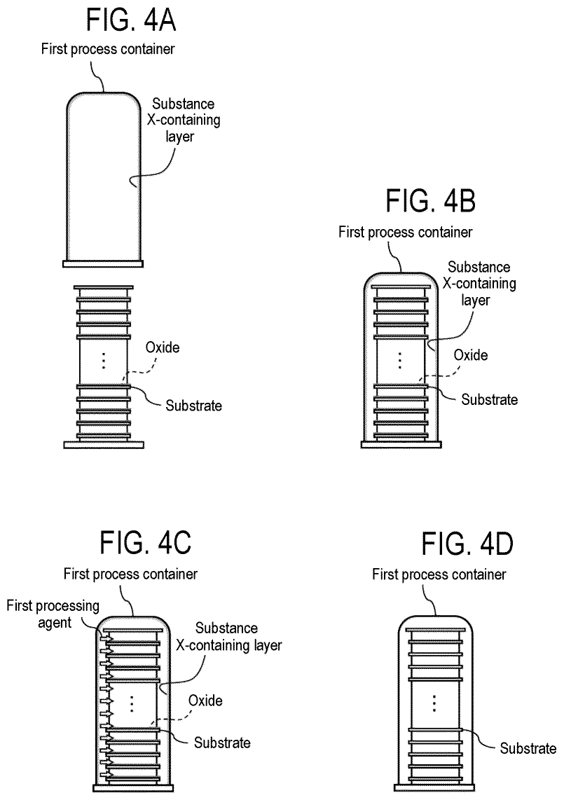

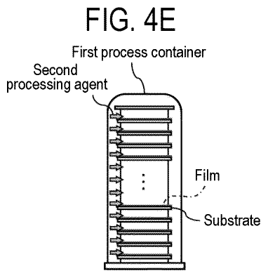

As a process (method) of manufacturing a semiconductor device by using the above-described processing apparatus, an example of a method of processing a substrate, that is, a processing sequence that successively performs a process of etching a surface of a wafer 200 as a substrate and a process of growing a film on the wafer 200 after etching, will be described mainly with reference to FIGS. 4A to 4E. In the following description, operations of the respective components constituting the processing apparatus are controlled by the controller 121. The processing apparatus is also be referred to as a substrate processing apparatus, an etching processing apparatus, an etching apparatus, a film formation processing apparatus, or a film formation apparatus, depending on the processing contents. The processing method is also be referred to as a substrate processing method, an etching processing method, an etching method, a film formation processing method, or a film formation method, depending on the processing contents.

A processing sequence in the embodiment includes:
(a) step A of preparing a first process container in which a substance X-Containing layer is formed;
(b) step B of loading a wafer 200 as a substrate into the first process container in which the substance X-containing layer is formed; and
(c) step C of supplying a first processing agent to the wafer 200 in the first process container in which the substance X-containing layer is formed, such that the first processing agent reacts with a substance X derived from the substance X-containing layer, thereby etching a surface of the wafer 200.

In the following example, a case will be described in which, in step A, the substance X-containing layer is formed on an inner wall of the first process container will be described. In addition, in the following example, a case will be described in which, in step A, a substance X-containing layer is formed in the first process container without the wafer 200 being loaded into the first process container.

In addition, in the following example, a case will be described in which, after step C, (d) step D of supplying a second processing agent to the wafer 200 with the surface etched, thereby processing the wafer, is further performed.

In addition, in the following example, a case will be described in which, in step D, a film-forming agent as a second processing agent is supplied to the wafer 200 with the surface etched, thereby forming a film on the wafer 200 with the surface etched.

When the term “wafer” is used in the present disclosure, it may refer to “a wafer itself” or “a wafer and a stacked body of certain layers or films formed on a surface of the wafer.” When the phrase “a surface of a wafer” is used in the present disclosure, it may refer to “a surface of a wafer itself” or “a surface of a certain layer formed on a wafer.” When the expression “a film is formed on a surface of a wafer” is used in the present disclosure, it may mean that “a film is formed directly on a surface of a wafer itself” or that “a film is formed on a film or the like formed on a wafer.” When the term “substrate” is used in the present disclosure, it may be synonymous with the term “wafer.”

The terms “agent” and “substance” used in the present disclosure include at least one selected from the group of a gaseous substance and a liquefied substance. The liquefied substance includes a misty substance. That is, each of the etching agent (F-containing substance), the film-forming agent (precursor, dopant agent), the reducing agent, and the pre-coating agent (precursor, catalyst, substance X) may include a gaseous substance, a liquefied substance such as a misty substance, or both of them.

### Step A

First, the shutter 219s is moved by the shutter opening/closing mechanism 115s to close the lower opening of the manifold 209, while the boat 217, that is, the wafer 200 is not loaded into the process chamber 201. In this state, the shutter 219s seals the lower end of the manifold 209 via the O-ring 220c (shutter close).

After that, an inside of the process chamber 201 is vacuum-exhausted (decompression-exhausted) by the vacuum pump 246 so as to reach a desired pressure (a degree of vacuum). At this time, an internal pressure of the process chamber 201 is measured by the pressure sensor 245, and the APC valve 244 is feedback-controlled based on the measured pressure information. Further, the process chamber 201 is heated by the heater 207 such that the inside of the process chamber 201 reaches a desired processing temperature. At this time, a state of supplying an electric power to the heater 207 is feedback-controlled based on the temperature information detected by the temperature sensor 263 such that a temperature distribution inside the process chamber 201 becomes a desired temperature distribution. Further, the exhaust and heating of the inside of the process chamber 201 are continuously performed at least until the processing of the inside of the process chamber 201 is completed.

Next, the following steps A1 and A2 are performed.

### Step A1

In step A1, a precursor and a catalyst are supplied as pre-coating agents into the process chamber 201 into which the wafers 200 are not yet loaded.

Specifically, the valves 243b and 243c are opened to allow the precursor and the catalyst to flow through the gas supply pipes 232b and 232c, respectively. Flow rates of the precursor and the catalyst are regulated by the MFCs 241b and 241c, respectively, and the precursor and the catalyst are supplied into the process chamber 201 via the nozzles 249b and 249c, respectively, mixed within the process chamber 201, and exhausted via the exhaust port 231a. At this time, the surface of the inner wall of the process chamber 201, i.e., the first process container, is exposed to the precursor and the catalyst (precursor+catalyst supply, exposure). At this time, the valves 243f to 243h may be opened to allow an inert gas to supplied into the process chamber 201 via the nozzles 249a to 249c, respectively.

After supplying the precursor and the catalyst into the process chamber 201 for a predetermined time, the valves 243b and 243c are closed to stop the supply of the precursor and the catalyst into the process chamber 201. The process chamber 201 is then vacuum-exhausted to remove a gaseous substance and the like remaining in the process chamber 201 from the process chamber 201. At this time, the valves 243f to 243h are opened to allow an inert gas to be supplied into the process chamber 201 via the nozzles 249a to 249c, respectively. The inert gas supplied from the nozzles 249a to 249c acts as a purge gas, whereby the inside of the process chamber 201 is purged (purging).

### Step A2

In step A2, a substance X and a catalyst are supplied as pre-coating agents into the process chamber 201 into which the wafers 200 are not yet loaded.

Specifically, the valves 243d and 243c are opened to allow the substance X and the catalyst to flow through the gas supply pipes 232d and 232c, respectively. Flow rates of the substance X and the catalyst are regulated by the MFCs 241d and 241c, respectively, and the substance X and the catalyst are supplied into the process chamber 201 via the nozzles 249a and 249c, respectively, mixed within the process chamber 201, and exhausted via the exhaust port 231a. At this time, the inside of the process chamber 201, i.e., the surface of the inner wall of the first process container, is exposed to the substance X and the catalyst (substance X+catalyst supply, exposure). At this time, the valves 243f to 243h may be opened to allow an inert gas to be supplied into the process chamber 201 via the nozzles 249a to 249c, respectively.

After supplying the substance X and the catalyst into the process chamber 201 for a predetermined time, the valves 243d and 243c are closed to stop the supply of the substance X and the catalyst into the process chamber 201. Then, a gaseous substance and the like remaining in the process chamber 201 are removed from the process chamber 201 (purging) according to the same processing procedures and processing conditions as the purging in step A1.

### Performing Predetermined Number of Times

Then, a cycle including steps A1 and A2 is performed a predetermined number of times (m times, where m is an integer of 1 or 2 or greater). As a result, as shown in FIG. 4A, a substance X-containing layer (pre-coating layer) with a desired thickness is formed inside the process chamber 201, i.e., on the inner wall of the first process container. When substances to be described later are used as the precursor, the substance X, and the catalyst, a layer containing an element (Si) contained in the precursor and the substance X (H₂O), i.e., a silicon oxide layer (SiO layer) containing water (H₂O) as the substance X, is formed as the substance X-containing layer.

The substance X contained in the substance X-containing layer formed on the inner wall of the first process container is released and supplied into the process chamber 201 in step C which will be described later. As will be described later, the substance X released into the process chamber 201 reacts with the first processing agent (etching agent) supplied into the process chamber 201 in step C to generate a predetermined reaction product (etching species), which acts to promote the etching reaction on the surface of the substrate. In other words, the substance X released from the substance X-containing layer functions as a reaction-promoting substance that promotes a progress of the etching reaction performed in step C.

Processing conditions when supplying the precursor and the catalyst in step A1 are exemplified as follows:
Processing temperature: room temperature (25 degrees C.) to 200 degrees C., specifically room temperature to 150 degrees C.
Processing pressure: 1 to 2,000 Pa, specifically 1 to 1,333 Pa
Processing time: 1 to 180 seconds, specifically 10 to 120 seconds
Supply flow rate of precursor: 0.001 to 2 slm, specifically 0.01 to 1 slm
Supply flow rate of catalyst: 0.001 to 2 slm, specifically 0,01 to 1 slm
Supply flow rate of inert gas (for each gas supply pipe): 0 to 10 slm, specifically to 5 slm.

In the present disclosure, the notation of a numerical range such as “25 to 200 degrees C.” means that a lower limit value and an upper limit value are included in the range. Therefore, for example, “25 to 200 degrees C.” means “25 degrees C. or higher and 200 degrees C. or lower.” The same applies to other numerical ranges. In the present disclosure, the processing temperature means a surface temperature of the object to be processed (in step A, a surface temperature of the interior of the process chamber 201, i.e., the inner wall of the first process container; in steps C and D, a surface temperature of the wafer 200 loaded into the process chamber 201). In the present disclosure, the processing pressure means an internal pressure of the process chamber 201. The processing time means a time during which a process is continued. In a case where 0 slm is included in the supply flow rate, it means a case where no substance (gas) is supplied. The same applies to the following description.

Processing conditions when supplying the substance X and the catalyst in step A2 are exemplified as follows:
Processing temperature: room temperature (25 degrees C.) to 200 degrees C., specifically room temperature to 150 degrees C.
Processing pressure: 1 to 2,000 Pa, specifically 1 to 1,333 Pa
Processing time: 1 to 180 seconds, specifically 10 to 120 seconds
Supply flow rate of substance X: 0.01 to 20 slm, specifically 0.01 to 10 slm
Supply flow rate of catalyst: 0.01 to 20 slm, specifically 0.01 to 10 slm
Supply flow rate of inert gas (for each gas supply pipe): 0 to 10 slm, specifically to 5 slm

An amount of substance X contained in the substance X-containing layer, i.e., a content, a concentration, a density, and a thickness of the substance X in the substance X-containing layer (hereinafter collectively referred simply to as a content, etc. of the substance X), may be controlled by regulating the above-described processing conditions. The content and the like of the substance X in the substance X-containing layer may be set to such an amount that most of the substance X is consumed (released into the process chamber 201) by performing step C which is performed subsequently. This suppresses the release of the substance X from the substance X-containing layer in step D which is performed after step C, thereby making it possible to prevent the substance X from affecting the processing of the substrate performed in step D. In a case where the substance X is still released from the substance X-containing layer after step C is completed, a process of removing and depleting the substance X from the substance X-containing layer (in a case where the substance X is water, this process is also referred to as a water depletion process) may be performed, for example, after performing step C and before performing step D by increasing the internal temperature of the process chamber 201. The processing temperature in this process may be higher than the processing temperature in steps A and C, specifically equal to or higher than the processing temperature in step D.

The precursor may be, for example, a silicon (Si)-containing substance. Examples of the precursor may include chlorosilanes such as monochlorosilane (SiH₃Cl), dichlorosilane (SiH₂Cl₂), trichlorosilane (SiHCl₃), tetrachlorosilane (SiCl₄), and hexachlorodisilane (Si₂Cl₆). Further, examples of the precursor may include silicon hydrides such as monosilane (SiH₄), disilane (Si₂H₆), trisilane (Si₃H₈), and tetrasilane (Si₄H₁₀). One or more of these may be used as the precursor.

The substance X may be, for example, a hydrogen (H)- and oxygen (O)- containing substance such as water (H₂O) or hydrogen peroxide (H₂O₂).

The catalyst may be, for example, a carbon (C)-, nitrogen (N)-, and H-containing substance. Examples of the catalyst may include chain amines such as triethylamine ((C₂H₅)₃N), diethylamine ((C₂H₅)₂NH), monoethylamine ((C₂H₅)NH₂), trimethylamine ((CH₃)₃N), dimethylamine ((CH₃)₂NH), and monomethylamine ((CH₃)NH₂). Further, examples of the catalyst may include cyclic amines such as aminopyridine (C₅H₆N₂), pyridine (C₅H₅N), picoline (C₆H₇N), lutidine (C₇H₉N), pyrimidine (C₄H₄N₂), quinoline (C₉H₇N), piperazine (C₄H₁₀N₂), piperidine (C₅H₁₁N), and aniline (C₆H₇N). One or more of these may be used as the catalyst.

The inert gas may be a nitrogen (N₂) gas or a rare gas such as an argon (Ar) gas, a helium (He) gas, a neon (Ne) gas, or a xenon (Xe) gas. One or more of these gases may be used as the inert gas. This also applies to steps to be described later.

After the formation of the substance X-containing layer on the inside of the process chamber 201, i.e., on the inner wall of the first process container, i.e., after preparation of the first process container in which the substance X-containing layer is formed, is completed, an inert gas is supplied as a purge gas from each of the nozzles 249a to 249c into the process chamber 201 and is exhausted via the exhaust port 231a. Thus, the inside of the process chamber 201 is purged, and gases, reaction by-products, and the like remaining in the process chamber 201 are removed from the inside of the process chamber 201 (after-purge). After that, the internal atmosphere of the process chamber 201 is substituted with an inert gas (inert gas substitution) and the internal pressure of the process chamber 201 is returned to a normal pressure (returning to atmospheric pressure).

### Step B

After that, or in parallel with the execution of Step A described above, a plurality of wafers 200 are charged into the boat 217 (wafer charging). Further, at least a portion of the wafer charging may be performed in parallel with the execution of Step A and completed before Step A is completed.

Oxides may be formed on the surfaces of the wafers 200. The oxides may include at least one selected from the group of a non-stoichiometric silicon oxide film (SiOₓ film, where x is a real number less than 2) and a stoichiometric silicon oxide film (SiO₂ film). The oxides may also include at least one selected from the group of a native oxide film and a chemical oxide film. Hereinafter, the SiOₓ film and the SiO₂ film are collectively referred to as a SiO film.

After the wafer charging is completed, the shutter 219s is moved by the shutter opening/closing mechanism 115s to open the lower end opening of the manifold 209 (shutter opening). Then, as shown in FIG. 1, the boat 217 supporting the wafers 200 is lifted up by the boat elevator 115 to be loaded into the process chamber 201 (boat loading). In this state, the seal cap 219 seals the lower end of the manifold 209 via the O-ring 220b.

Upon completion of the boat loading, as shown in FIG. 4B, the wafers 200 serving as substrates are loaded (placed) into the first process chamber in which the substance X-containing layer is formed. The substance X-containing layer is positioned adjacent to but separate from the wafers 200 serving as substrates.

### Pressure Regulation and Temperature Regulation

After the boat loading is completed, the inside of the process chamber 201, that is, a space where the wafers 200 are placed, is vacuum-exhausted (decompression-exhausted) by the vacuum pump 246 so as to reach a desired pressure (degree of vacuum). Further, the wafers 200 in the process chamber 201 are heated by the heater 207 so as to have a desired processing temperature. Further, the rotation of the wafers 200 by the rotator 267 is started. The exhaust of the inside of the process chamber 201 and the heating and rotation of the wafers 200 are continuously performed at least until the processing on the wafers 200 is completed.

### Step C

After that, an etching agent is supplied as a first processing agent to the wafers 200 in the process chamber 201.

Specifically, the valve 243a is opened to allow the etching agent to flow into the gas supply pipe 232a. Flow rate of the etching agent is regulated by the MFC 241a, and the etching agent is supplied into the process chamber 201 via the nozzle 249a and is exhausted via the exhaust port 231a. At this time, as shown in FIG. 4C, the etching agent is supplied to the wafers 200 from a lateral side of the wafers 200 as substrates, exposing the wafer 200 to the etching agent as the first processing agent (etching agent supply, exposure). At this time, the valves 243f to 243h may be opened to allow an inert gas to be supplied into the process chamber 201 via the nozzles 249a to 249c, respectively.

By supplying the etching agent to the wafers 200 under processing conditions to be described later, the etching agent reacts with the substance X derived from the substance X-containing layer, such that the surfaces of the wafers 200 may be etched, as shown in FIG. 4D.

For example, in a case where the oxide on the surface of the wafer 200 contains silicon oxide (SiO₂), the substance X-containing layer previously formed inside the process chamber 201 contains water (H₂O) as the substance X, and the etching agent as the first processing agent supplied into the process chamber 201 contains hydrogen fluoride (HF) as the F-containing substance, a reaction shown in the following formula may proceed under the conditions to be described later. That is, the oxide (SiO₂) formed on the surface of the wafer 200 may be etched and removed by using etching species (e.g., HF₂⁻) obtained by the reaction between the substance X (H₂O) and the etching agent (HF).

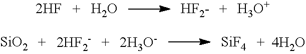

As described above, according to the present disclosure, the etching of oxide (SiO₂) on the surface of the wafer 200 may be triggered by a reaction between the etching agent (HF) as the first processing agent supplied into the process chamber 201 and a trace amount of substance X (H₂O) derived from the substance X-containing layer previously formed in the process chamber 201. When the etching of oxide is started, the trace amount of substance X (H₂O) previously contained in the substance X-containing layer formed in the process chamber 201 is consumed. FIG. 4D schematically illustrates a state in which, by performing step C, the surface of the wafer 200 as a substrate is etched and most of the substance X contained in the substance X-containing layer is consumed (released).

However, in the reaction system in step C, water (H₂O) is generated by the etching of oxide. Therefore, in step C, the above-mentioned reaction may be repeated successively without additionally supplying the substance X into the process chamber 201, thereby etching the oxide on the surface of the wafer 200. In a case where the substance X is additionally supplied into the process chamber 201 in step C, an amount of substance X in the reaction system may become excessive, which may rather hinder the progress of the etching reaction.

Further, the substance X is released in a substantially uniform amount across the entire substrate arrangement direction in the process chamber 201. Therefore, an effect of promoting the etching reaction by the substance X may be uniformly obtained among the plurality of substrates in the process chamber 201, thereby making it possible to improve inter-substrate uniformity of the etching amount on the surfaces of the substrates.

After etching the surface of the wafer 200, the valve 243a is closed to stop the supply of the etching agent into the process chamber 201. Then, a gaseous substance and the like remaining in the process chamber 201 are removed from the process chamber 201 (purging) according to the same processing procedures and processing conditions as the purging in step A1.

Processing conditions when supplying the etching agent in step C are exemplified as follows:
Processing temperature: room temperature (25 degrees C.) to 170 degrees C., specifically 25 to 150 degrees C.
Processing pressure: 10 to 4,000 Pa, specifically 500 to 2,000 Pa
Processing time: 1 to 120 minutes, specifically 10 to 100 minutes
Supply flow rate of etching agent: 0.5 to 3 slm, specifically 1 to 2 slm
Supply flow rate of inert gas (for each gas supply pipe): 0 to 10 slm, specifically to 5 slm.

Herein, in a case where the processing temperature when supplying the etching agent in step C is set to be lower than room temperature (25 degrees C.), the etching rate may be increased, but in a case where other process such as a film formation process is performed before and/or after the etching process, a time for changing the processing temperature between the etching process and the other process (a time for raising the temperature and/or a time for lowering the temperature) may become too long, resulting in reduced productivity.

By setting the processing temperature to be equal to or higher than room temperature (25 degrees C.), the time for changing the processing temperature between the etching process and the other process may be shortened while maintaining a high etching rate, thereby preventing the reduction of productivity.

Furthermore, in a case where the processing temperature is set to be higher than 170 degrees C., the time for changing the processing temperature between the etching process and the other process may be significantly shortened, but the etching rate may become too low, resulting in the reduction of productivity.

By setting the processing temperature to be equal to lower than 170 degrees C., it is possible to suppress a decrease in etching rate while maintaining a significant reduction in the time for changing the processing temperature between the etching process and other process, and thus to suppress the reduction in productivity. By setting the processing temperature to be equal to or lower than 150 degrees C., it is possible to further suppress a decrease in etching rate while maintaining a significant reduction in the time for changing the processing temperature between the etching process and other process, and thus to further suppress the reduction in productivity. By setting the processing temperature to be equal to or lower than 130 degrees C., it is possible to significantly suppress a decrease in etching rate while maintaining a significant reduction in the time for changing the processing temperature between the etching process and other process, and thus to significantly suppress the reduction in productivity.

In light of the above, the processing temperature may be set to a range from room temperature (25 degrees C.) to 170 degrees C., specifically from 25 degrees C. to 150 degrees C., and more specifically from 25 degrees C. to 130 degrees C.

As described above, as the first processing agent (etching agent), a F-containing substance, for example, a F- and H-containing substance such as HF, may be used. Further, for example, as the first processing agent, a F-containing substance such as fluorine (F₂), nitrogen trifluoride (NF₃), chlorine trifluoride (ClF₃), or chlorine fluoride (ClF), a F- and N-containing substance, or a F- and Cl-containing substance, may be used. One or more of these may be used as the first processing agent.

### Step D

After that, a precursor, which is a film-forming agent, is supplied as a second processing agent to the wafer 200 with surface etched. At this time, a reducing agent is also supplied along with the precursor.

Specifically, valves 243b and 243e are opened to allow the precursor and the reducing agent to flow through the gas supply pipes 232b and 232e, respectively. Flow rates of the precursor and the reducing agent are regulated by the MFCs 241b and 241e, respectively, and the precursor and the reducing agent are supplied into the process chamber 201 via the nozzle 249b and are exhausted via the exhaust port 231a. At this time, as shown in FIG. 4E, the precursor and the reducing agent as the second processing agents are supplied to the wafer 200 from the lateral side of the wafers 200 as substrates, exposing the wafers 200 to the precursor and the reducing agent (precursor+reducing agent supply, exposure). At this time, the valves 243f to 243h may be opened to allow an inert gas to be supplied into the process chamber 201 via the nozzles 249a to 249c, respectively.

By supplying the precursor and the reducing agent to the wafers 200 under processing conditions to be described later, a film with a desired thickness can be formed on the surface of the wafer 200 after etching. For example, in a case where the surface of the wafer 200 exposed by the etching process is constituted by single crystal Si and substances to be described later are used as the precursor and the reducing agent, an epitaxial Si film can be grown and formed on the surface of the wafer 200. At this time, by the action of the reducing agent, the surface of the wafer 200 and the inside of the process chamber 201 may be maintained in a clean state, thereby enabling proper epitaxial growth and allowing a high-purity epitaxial Si film to be formed.

After forming the film with the desired thickness on the surface of the wafer 200, the valves 243b and 243e are closed to stop the supply of the precursor and the reducing agent into the process chamber 201. Then, the interior of the process chamber 201 is purged according to the same processing procedures and processing conditions as the purging in step A1.

Processing conditions when supplying the precursor and the reducing agent in step D are exemplified as follows:
Processing temperature: 500 to 650 degrees C, specifically 550 to 600 degrees C.
Processing pressure: 4 to 200 pa, specifically 1 to 120 Pa
Processing time: 10 to 120 minutes, specifically 20 to 60 minutes
Supply flow rate of precursor: 0.1 to 5 slm, specifically 0.2 to 3 slm
Supply flow rate of reducing agent: 1 to 20 slm, specifically 1 to 10 slm
Supply flow rate of inert gas (for each gas supply pipe): 0 to 10 slm, specifically 0.1 to 5 slm

Examples of the second processing agent (precursor) may include silicon hydrides such as SiH₄, Si₂H₆, Si₃H₈, and Si₄H₁₀. Further, example of the precursor may include chlorosilanes such as SiH₃Cl, SiH₂Cl₂, SiHCl₃, SiCl₄, and Si₂Cl₆. One or more of these may be used as the precursor.

The reducing agent may be, for example, a H-containing substance or a deuterium (D)-containing substance such as hydrogen (H₂) or deuterium (D₂). One or more of these may be used as the reducing agent.

### After-Purge and Returning to Atmospheric Pressure

After step D is completed, an inert gas acting as a purge gas is supplied into the process chamber 201 from each of the nozzles 249a to 249c and is exhausted via the exhaust port 231a. Thus, the inside of the process chamber 201 is purged and gases, reaction by-products, and the like remaining in the process chamber 201 are removed from the process chamber 201 (after-purge). After that, the internal atmosphere of the process chamber 201 is substituted with an inert gas (inert gas substitution) and the internal pressure of the process chamber 201 is returned to the normal pressure (returning to atmospheric pressure).

### Boat Unloading

After that, the seal cap 219 is moved down by the boat elevator 115 to open the lower end of the manifold 209. Then, the processed wafers 200 supported by the boat 217 are unloaded from the lower end of the manifold 209 to the outside of the reaction tube 203 (boat unloading). After the boat unloading, the shutter 219s is moved and the lower end opening of the manifold 209 is sealed by the shutter 219s via the O-ring 220c (shutter closing). After the boat unloading, the processed wafers 200 are discharged from the boat 217 (wafer discharging).

This completes the processing process in the embodiments of the present disclosure.

Further, as in the embodiments, steps C and D may be performed in the same process container (in situ). When a series of processes are performed in-situ, the wafer 200 is not exposed to the atmosphere in the middle of the processes, making it possible to perform a consistent and stable process while the wafer 200 is placed under vacuum.

### (3) Effects of the Embodiment

According to the embodiment, one or more effects set forth below may be achieved.

(a) Step A of preparing a first process container in which a substance X-containing layer is formed, step B of loading a substrate into the first process container in which the substance X-containing layer is formed, and step C of supplying a first processing agent to the substrate in the first process container in which the substance X-containing layer is formed, such that the first processing agent reacts with the substance X derived from the substance X-containing layer, thereby etching the surface of the substrate are performed. That is, in step C, when etching the surface of the substrate, the first processing agent supplied in step C reacts with the substance X derived from the substance X-containing layer formed in the first process container prior to step B. This allows the first processing agent to react with a trace amount of substance X in step C, thereby promoting the etching reaction. As a result, the surface of the substrate may be etched efficiently.

Furthermore, step B allows the substance X-containing layer to be positioned adjacent to but separate from the substrate. By performing step C in this state, the substance X is released in a substantially uniform amount across the entire substrate arrangement direction in the first process container, thereby improving uniformity of the etching process, particularly inter-substrate uniformity.

Furthermore, the processing temperature in the etching process performed in step C may be increased. Therefore, in a case where other process, such as the film formation process, is performed before and/or after the etching process, the processing temperature in the etching process may be brought closer to the processing temperature in the other process. This reduces the time for changing the processing temperature between the etching process and other process, i.e., at least one selected from the group of the time for raising the temperature and the time for lowering the temperature, thereby improving productivity.

(b) In step A, the substance X-containing layer is formed on the inner wall of the first process container. This makes it possible to effectively arrange the substance X-containing layer in step B at a position that is equally separate from and adjacent to each substrate. As a result, it is possible to further improve the uniformity of the etching process performed in step C, in particular the inter-substrate uniformity of the etching process.

(c) In step A, the substance X-containing layer is formed in the first process container without any substrates being loaded into the first process container. This makes it possible to form the substance X-containing layer in step A at a specific location in the first process container, for example, on the inner wall of the first process container, without being formed on the substrate. That is, in step A, it is possible to prevent the substance X-containing layer from being formed on the entire surface (front, back, and side surfaces) of the substrate or on any members present in the space within the first process container.

This makes it possible to cause the first processing agent to react with the trace amount of substance X in step C effectively, thereby effectively promoting the etching reaction. As a result, it is possible to more efficiently etch

### The Surface of the Substrate.

In addition, it is possible to minimize the amount of substance X remaining in the first process container after etching (hereinafter referred to as a residual substance X), thereby suppressing an influence of the residual substance X on the substrate after etching.

(d) In step A, the precursor, the substance X, and the catalyst are supplied into the first process container, and a layer containing an element contained in the precursor and the substance X is formed as the substance X-containing layer. This makes it possible to efficient prepare the first process container in which the substance X-containing layer is formed.

(e) The substance X contains a H-and O-containing substance such as H₂O. This makes it possible to effectively achieve the above-described effects.

(f) The first processing agent contains a F-containing substance such as a F- and H-containing substance. This makes it possible to effectively achieve the above-described effects.

(g) In step C, oxides formed on the surface of the substrate, including at least one selected from the group of a native oxide film and a chemical oxide film, are removed. This makes it possible to effectively achieve the above-described effects.

(h) In step D, the second processing agent is supplied to the substrate with the surface etched and cleaned, to process the substrate. This makes it possible to efficiently process the substrate.

(i) In step D, the precursor, which is a film-forming agent, is supplied as the second processing agent to the substrate the surface etched, to form a film on the substrate with the surface etched. This makes it possible to reduce an impurity concentration (an oxygen concentration, etc.) at an interface between the substrate and the film.

(j) The above-described effects may be similarly achieved even when using a predetermined substance arbitrarily selected from the above-mentioned various pre-coating agents (precursor, substance X, catalyst), various first processing agents (etching agents), various second processing agents (precursors), various reducing agents, and various inert gases.

### Second Embodiment of the Present Disclosure

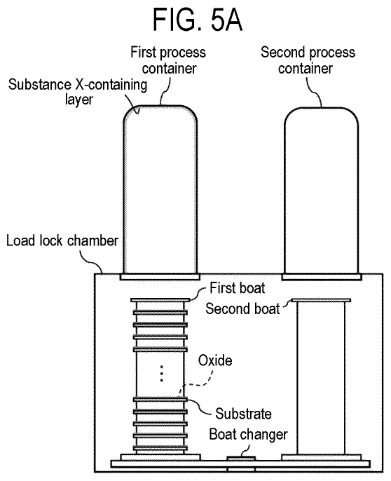

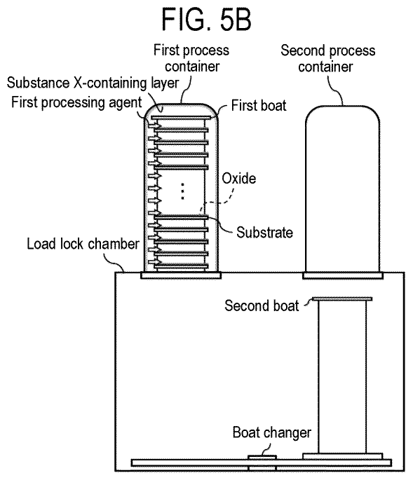

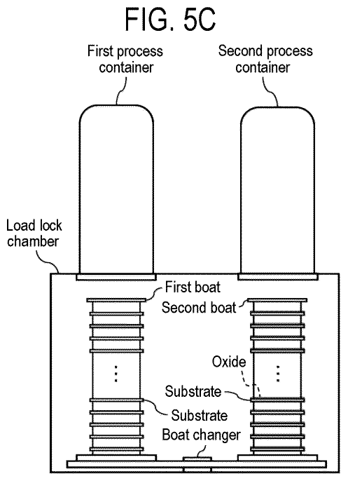

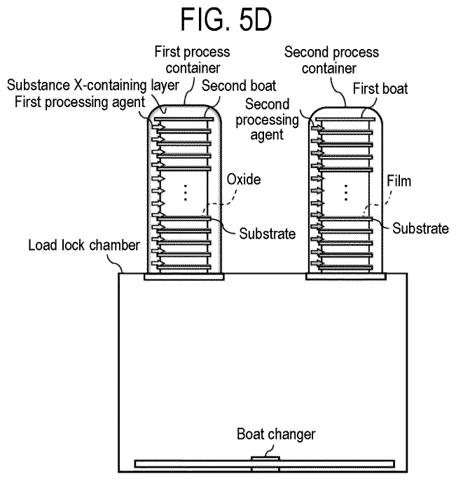

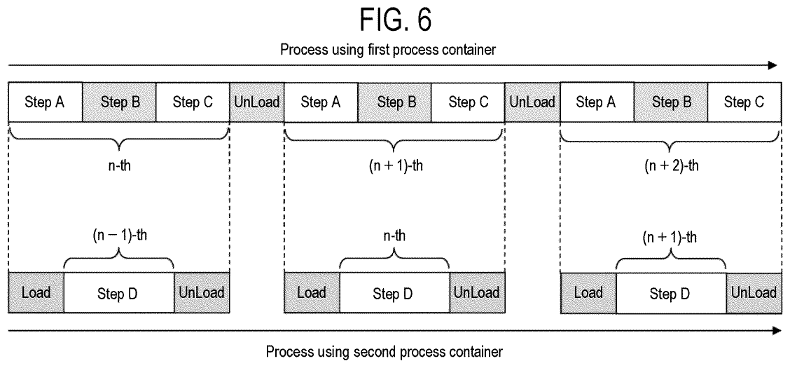

Next, a second embodiment of the present disclosure will be described mainly with reference to FIGS. 5A to 5D and 6. This embodiment is different from the above-described first embodiment in that steps C and D are performed in different process containers (ex-situ). In this embodiment, step C is performed in the first process container, and step D is performed in the second process container. Except for this point, processing procedures and processing conditions for steps A to D of this embodiment are the same as those for steps A to D of the first embodiment. In this embodiment, the second process container may be supplied with the film-forming agent, the reducing agent, and the inert gas from the film-forming agent supply system, the reducing agent supply system, and the inert gas supply system, respectively. The configuration of the second process container is the same as that of the first process container except for the supply system related to the second process container.

First, as shown in FIG. 5A, step A is performed to prepare the first process container in which a substance X-containing layer, i.e., a layer capable of releasing a substance X as a reaction-promoting substance is formed. In this embodiment, the first process container and the second process container are each connected to a load lock chamber. The load lock chamber constitutes an airtight container whose interior may be set to a vacuum or non-atmospheric environment. A transport mechanism (boat changer, boat elevator, etc.) is installed within the load lock chamber. The transport mechanism is configured to be capable of transporting first and second boats, which serve as substrate supports, into the first and second process containers in the vacuum or non-atmospheric environment.

After that, as shown in FIG. 5B, step B is performed such that a substrate with an oxide formed on its surface is loaded, while being supported by the first boat, into the first process container in which the substance X-containing layer is formed. Then, step C is performed to supply the first processing agent to the substrate in the first process container in which the substance X-containing layer is formed, such that the first processing agent reacts with the substance X derived from the substance X-containing layer, thereby etching the surface of the substrate to remove the oxide formed on the surface of the substrate.

After that, as shown in FIG. 5C, the first boat supporting the substrate with the surface etched is unloaded from the first process container into the load lock chamber.

After that, the boat changer changes positions of the first boat supporting the substrate with the surface etched and the second boat supporting the substrate with the oxide formed on the surface and loads the first boat supporting the substrate with the surface etched into the second process container in the vacuum or non-atmospheric environment, as shown in FIG. 5D. Then, in a state where the substrate with the surface etched is loaded into the second process container, step D is performed to supply a film-forming agent as the second processing agent to the substrate with the surface etched to form a film on the substrate with the surface etched. In parallel, steps A to C described above are performed again. That is, the first process container in which the substance X-containing layer is formed is prepared. After that, the substrate with the oxide formed on the surface is loaded, while being supported by the second boat, into the first process container in which the substance X-containing layer is formed. Then, the first processing agent is supplied to the substrate in the first process container in which the substance X-containing layer is formed and reacts with the substance X derived from the substance X-containing layer to etch the surface of the substrate, thereby removing the oxide formed on the surface of the substrate.

This embodiment also achieves the same effects as the above-described embodiment.

Furthermore, according to this embodiment, step D is performed in a state where the substrate with the surface etched is loaded into the second process container. In this way, by performing steps C and D ex-situ, it is possible to prevent the substance X or the first processing agent from being introduced into the second process container and to prevent the second processing agent from being introduced into the first process container. This prevents cross-contamination within each process container, thereby improving a quality of the processing performed in each process container.

Furthermore, according to the embodiment, the substrate with the surface etched is transported from the inside of the first process container to the inside of the second process container in the vacuum or non-atmospheric environment. This prevents the substrate from being exposed to the atmosphere after step C is performed, thereby keeping the etched and cleaned surface of the substrate clean until step D is performed and preventing oxidation of the surface.

In this embodiment, in a case where steps A to D are performed a plurality of times, a period during which the step D for an n-th time and at least one selected from the group of the steps A to C for an (n+1)-th time are performed in parallel may be provided. FIGS. 5A to 5D and 6 illustrates a case in which an execution period of the step D for the n-th time using the second process container and a total execution period of the steps A to C for the (n+1)-th time using the first process container partially overlap with each other.

Such parallel processing may be achieved, for example, by preparing a plurality of boats (first and second boats) in the load lock chamber and transporting the same by using a boat exchange apparatus (boat changer) and the like. As described above, after the steps A to C for the n-th time are performed, the first boat supporting the substrate with the surface etched is unloaded from the first process container into the load lock chamber (Unload), as shown in FIG. 5C. Until or after the first boat is completely unloaded, a new substrate (e.g., a substrate with an oxide formed on its surface) to be subjected to the processing for (n+1)-th time is charged into the second boat. After this processing is completed, the boat changer exchanges the positions of the first and second boats and loads the first boat into the second process container (Load). Then, as shown in FIG. 5D, the step D for the n-th time using the second process container and at least one selected from the group of the steps A to C for the (n+1)-th time using the first process container are performed in parallel.

According to the above, in a case where steps A to D are performed a plurality of times, a total processing time may be shortened, thereby improving productivity.

### Third Embodiment of the Present Disclosure

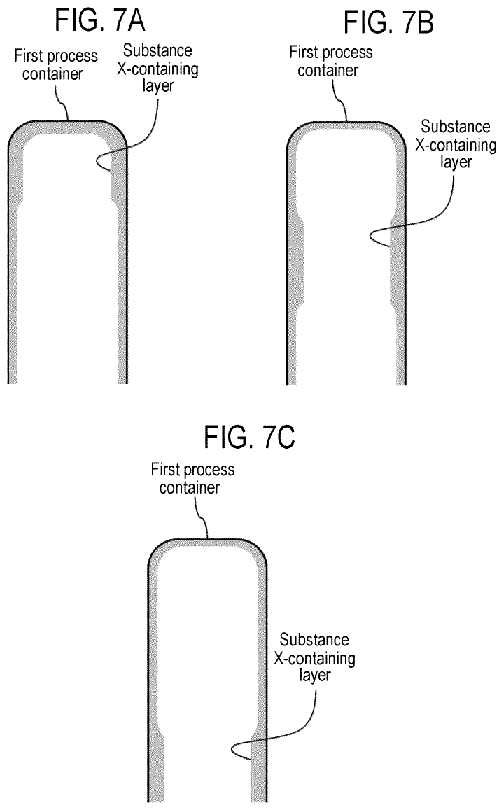

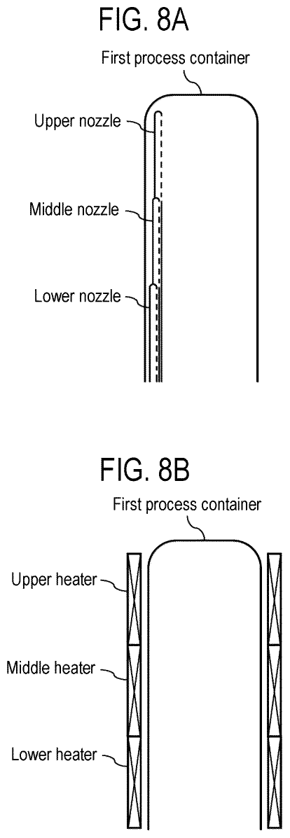

Next, a third embodiment of the present disclosure will be described mainly with reference to FIGS. 7A to 7C and FIGS. 8A and 8B.

When performing step C, there may be a portion within the first process container where the substance X becomes insufficient. In such a case, the substance X-containing layer corresponding to the portion within the first process container where substance X is insufficient may be made thicker than other portions. Alternatively, a content, a concentration, and a density of substance X in the substance X-containing layer corresponding to the portion within the first process container where the substance X is insufficient may be made greater (higher) than those in other portions. That is, in step A, at least one selected from the group of the content of the substance X in the substance X-containing layer, the concentration of the substance X in the substance X-containing layer, the density of the substance X in the substance X-containing layer, and the thickness of the substance X-containing layer may be made different between one portion and another portion in the first process container.

For example, when performing step C, in a case where the substance X becomes insufficient in an upper portion of the first process container, the substance X-containing layer formed in the upper portion of the first process container may be made thicker than the substance X-containing layers formed in other portions (middle and lower portions) of the first process container, as shown in FIG. 7A. In addition, the content, concentration, and density of substance X of the substance X-containing layer formed in the upper portion in the first process container may be made greater than the content, concentration, and density of substance X of the substance X-containing layers formed in other portions of the first process container.

Furthermore, for example, when performing step C, in a case where the substance X becomes insufficient in the middle portion of the first process container, the substance X-containing layer formed in the middle portion of the first process container may be made thicker than the substance X-containing layers formed in other portions (upper and lower portions) of the first process container, as shown in FIG. 7B. In addition, the content, concentration, and density of substance X in the substance X-containing layer formed in the middle portion of the first process container may be made greater than the content, concentration, and density of substance X in the substance X-containing layers formed in other portions of the first process container.

Furthermore, for example, when performing step C, in a case where the substance X becomes insufficient in the lower portion of the first process container, the substance X-containing layer formed in the lower portion of the first process container may be made thicker than the substance X-containing layers formed in other portions (upper and middle portions) of the first process container, as shown in FIG. 7C. In addition, the content, concentration, and density of substance X in the substance X-containing layer formed in the lower portion of the first process container may be made greater than the content, concentration, and density of substance X in the substance X-containing layers formed in other portions of the first process container.

In any case, one or more portions within the first process container may be installed in which at least one selected from the group of the content of the substance X in the substance X-containing layer, the concentration of the substance X in the substance X-containing layer, the density of the substance X in the substance X-containing layer, and the thickness of the substance X-containing layer is made different from those of other portions. In addition, in any case, at least one selected from the group of the content of the substance X in the substance X-containing layer, the concentration of the substance X in the substance X-containing layer, the density of the substance X in the substance X-containing layer, and the thickness of the substance X-containing layer may be made different stepwise (in multiple stages) according to the position within the first process container. Furthermore, in any case, at least one selected from the group of the content of the substance X in the substance X-containing layer, the concentration of the substance X in the substance X-containing layer, and the density of the substance X in the substance X-containing layer may be made different according to the position within the first process container, without or with the thickness of the substance X-containing layer being made different according to the position within the first process container.

Note that, for example, by using the process furnace shown in FIG. 8A or the process furnace shown in FIG. 8B, the content, and the like of substance X in the substance X-containing layer may be made different between one portion and another portion within the first process container.

The process furnace shown in FIG. 8A includes multiple nozzles (upper nozzle, middle nozzle, and lower nozzle) respectively corresponding to the upper, middle, and lower portions in the first process container. In step A, by individually controlling flow rates, concentrations, and type of pre-coating agents supplied from the upper, middle, and lower nozzles to be varied, at least one selected from the group of the content of the substance X in the substance X-containing layer, the concentration of the substance X in the substance X-containing layer, the density of the substance X in the substance X-containing layer, and the thickness of the substance X-containing layer may be made different between one portion and another portion in the first process container.

The process furnace shown in FIG. 8B also includes a multi-zone heater including an upper heater, a middle heater, and a lower heater installed to correspond to the upper, middle, and lower portions in the first process container, respectively. In step A, by individually controlling the heating conditions of the upper heater, the middle heater, and the lower heater to be different from one another, at least one selected from the group of the content of the substance X in the substance X-containing layer, the concentration of the substance X in the substance X-containing layer, the density of the substance X in the substance X-containing layer, and the thickness of the substance X-containing layer may be made different between one portion and another portion in the first process container. Further, the multi-zone heater may not be limited to including three zones, and may include four, five, or more zones.

This embodiment also achieves the same effects as the above-described embodiment.

Furthermore, according to this embodiment, in step C, an etching amount of the surface of the substrate may be regulated depending on the position within the first process container. This makes it possible, for example, to suppress variation in the etching amount of the surface of the substrate depending on the position within the first process container, i.e., among the substrates.

### Other Embodiments of the Present Disclosure

The embodiments of the present disclosure are specifically described above. However, the present disclosure is not limited to the above-described embodiments, and various changes may be made without departing from the spirit and scope of the present disclosure.

The substance X-containing layer may be any layer capable of releasing the substance X, which serves as a reaction-promoting substance that promotes the etching reaction, into the first process container (i.e., supplying the substance X into the process container). A layer other than a SiO layer containing water as the substance X may also be used as the substance X-containing layer. For example, in step A, the precursor and catalyst containing Si and carbon (C), such as bis(trimethylsilyl)methane, and H2O and catalyst as the substance X may be alternately supplied into the first process container. In this case, a layer containing elements (Si, C) contained in the precursor and H₂O as the substance X, i.e., a silicon oxycarbide (SiOC) layer containing water as the substance X, may be formed as the substance X-containing layer in the first process container. This embodiment also achieves the same effects as the above-described embodiments.

Furthermore, for example, in step A, the precursor, and the substance X and catalyst may be alternately supplied into the first process container. Furthermore, in step A, the precursor and catalyst, and the substance X may be alternately supplied into the first process container. That is, in step A, the catalyst may be supplied into the first process container together with at least one selected from the group of the precursor and the substance X. Also in this embodiment, it is possible to form, within the first process container, a layer serving as the substance X-containing layer that contains an element contained in the precursor and the substance X, thereby achieving the same effects as in the above-described embodiments.

Furthermore, for example, in step A, the precursor and the substance X may be supplied as pre-coating agents into the first process container without supplying a catalyst. Also in this embodiment, it is possible to form, within the first process container, a layer serving as the substance X-containing layer that contains an element contained in the precursor and the substance X, thereby achieving the same effects as in the above-described embodiments.

Furthermore, for example, in step A, the substance X may be supplied as a pre-coating agent into the first process container without supplying any precursor or catalyst. In this case, an adsorption layer of substance X may be formed as the substance X-containing layer in the first process container. In a case where the substance X is H₂O, the substance X-containing layer may be a liquid film. Further, the substance X may be H₂O₂ or a substance other than H₂O or H₂O₂; in general, any H- and O-containing substance may be used as the substance X. After forming the adsorption layer of substance X, the thickness of the adsorption layer of substance X, the content of substance X in the adsorption layer of substance X, etc. may be regulated by purging the inside of the first process container. Such regulation may also be performed by regulating processing conditions including an exposure amount of substance X when forming the adsorption layer of substance X, or an exposure amount of a purge gas when purging the inside of the first process container. Furthermore, by changing the exposure amount of substance X or the exposure amount of the purge gas depending on the position within the first process container, the thickness of the adsorption layer of substance X, the content of substance X in the adsorption layer of substance X, etc. may be varied and regulated depending on the position within the first process container. Such regulation may be achieved, for example, by using the process furnace shown in FIG. 8A. This embodiment also achieves the same effects as the above-described embodiments.

Furthermore, for example, in step A, after forming a layer capable of absorbing or adsorbing the substance X in the first process container, the substance X may be supplied into the first process container to form a layer where the substance X is absorbed or adsorbed, as the substance X-containing layer. For example, in step A, after forming a hydrophilic layer with hygroscopic and water-absorptive properties in the first process container, H₂O may be supplied as the substance X into the first process container to form a layer where water is absorbed and/or adsorbed, in the hydrophilic layer. The hydrophilic layer may be a SiO layer or a layer formed by the above-described method, i.e., a SiO layer or SiOC layer containing water. In a case where a SiO layer is used as the hydrophilic layer, the supply of H₂O may form a layer where water is newly absorbed and/or adsorbed in the SiO layer, as the substance X-containing layer. Furthermore, since the layer (SiO layer or SiOC layer containing water) formed by the above-described method contain water immediately after the formation, in a case where this layer is used as the hydrophilic layer, the supply of H₂O may modify the layer such that its water content increases. Further, by changing the exposure amount of H₂O, i.e., the supply amount and flow rate of H₂O, depending on the position within the first process container, the content, and the like of substance X in the substance X-containing layer may be varied and regulated depending on the position within the first process container. This embodiment also achieves the same effects as the above-described embodiments.

Furthermore, for example, step A may be performed with an empty substrate holder (not charged with a substrate) loaded into the first process container. In this case, the substance X-containing layer with a desired thickness is formed on the inner wall of the first process container, the surface of the substrate holder, and the like. This embodiment also achieves the same effects as the above-described embodiments.

Furthermore, for example, in step D, a dopant agent may be supplied as a film-forming agent to the substrate in addition to the precursor and the reducing agent. The dopant agent may be supplied from the aforementioned film-forming agent supply system. The dopant agent may be a substance containing a Group XV element such as phosphorus (P) or arsenic (As), and a Group XIII element such as boron (B). Examples of the dopant agent may include phosphine (PH₃), arsine (AsH₃), diborane (B₂H₆), trichloroborane (BCl3), and the like. One or more of these may be used as the dopant agent. This embodiment also achieves the same effects as the above-described embodiments. Furthermore, according to this embodiment, it is possible to form a film doped with a dopant (P, As, B, etc.) on the substrate.

Furthermore, for example, in step D, a substance containing a semiconductor element other than Si may be used to form a semiconductor element-containing film on the substrate. For example, a substance containing germanium (Ge), such as monogermane (GeH₄), may be used as the precursor to form a Ge-containing film on the substrate. Alternatively, for example, Si-containing substance and Ge-containing substance may be used as the precursor to form a Si- and Ge-containing film on the substrate. Alternatively, for example, a substance containing a metal element such as tungsten (W), molybdenum (Mo), aluminum (Al), titanium (Ti), zirconium (Zr), hafnium (Hf), or tantalum (Ta) may be used as the precursor to form a metal element-containing film on the substrate. In these cases, the same effects as the above-described embodiments may be achieved.

Furthermore, for example, in step D, in addition to the epitaxial film, an amorphous film, a polycrystalline film (poly film), or a mixed crystal film thereof may be formed on the substrate. In these cases, the same effects as the above-described embodiments may be achieved.

Furthermore, for example, in step D, instead of performing the process of forming a film on the substrate, a process of modifying the surface of the substrate to a predetermined surface may be performed, or a process of etching the surface of the substrate may be performed. In these cases, the same effects as the above-described embodiments may be achieved.

Recipes used in each process may be prepared individually according to the processing contents and may be recorded and stored in the memory 121c via a telecommunication line or the external memory 123. Moreover, at the beginning of each process, the CPU 121a may properly select an appropriate recipe from the recipes recorded and stored in the memory 121c according to the processing contents. Thus, it is possible for the processing apparatus to perform various processes with enhanced reproducibility. Further, it is possible to reduce an operator's burden and to quickly start each process while avoiding an operation error.

The recipes mentioned above are not limited to newly-prepared ones but may be prepared, for example, by modifying existing recipes that are already installed in the processing apparatus. Once the recipes are modified, the modified recipes may be installed in the processing apparatus via a telecommunication line or a recording medium storing the recipes. In addition, the existing recipes already installed in the existing processing apparatus may be directly modified by operating the input/output device 122 of the processing apparatus.

An example in which a process is performed by using a batch-type processing apparatus capable of processing a plurality of substrates at a time is described in the above-described embodiments. The present disclosure is not limited to the above-described embodiments, but may be applied, for example, to a case where a process is performed by using a single-wafer type processing apparatus capable of processing a single substrate or several substrates at a time. In addition, an example in which a process is performed by using a processing apparatus provided with a hot-wall-type process furnace is described in the above-described embodiments. The present disclosure is not limited to the above-described embodiments, but may be applied to a case where a process is performed by using a processing apparatus provided with a cold-wall-type process furnace.

Even in the case of using these processing apparatuses, each process may be performed according to the same processing procedures and processing conditions as those in the above-described embodiments and modifications, and the same effects as the above-described embodiments and modifications may be obtained.

The above-described embodiments and modifications may be used in proper combination. Processing procedures and processing conditions used in this case may be the same as, for example, the processing procedures and processing conditions in the above-described embodiments and modifications.

According to the present disclosure in some embodiments, it is possible to efficiently etch the surface of a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A processing method comprising:
(a) preparing a first process container in which a substance X-containing layer is formed;
(b) loading a substrate into the first process container in which the substance X-containing layer is formed; and
(c) supplying a first processing agent to the substrate in the first process container in which the substance X-containing layer is formed, such that the first processing agent reacts with a substance X derived from the substance X-containing layer, thereby etching a surface of the substrate.

2. The processing method of claim 1, wherein in (a), the substance X-containing layer is formed on an inner wall of the first process container.

3. The processing method of claim 1, wherein in (a), the substance X-containing layer is formed in the first process container, with the substrate not loaded into the first process container.

4. The processing method of claim 1, wherein in (a), the substance X is supplied into the first process container.

5. The processing method of claim 4, wherein in (a), an adsorption layer of the substance X is formed as the substance X-containing layer.

6. The processing method of claim 1, wherein in (a), a precursor and the substance X are supplied into the first process container, or the precursor, the substance X, and a catalyst are supplied into the first process container.

7. The processing method of claim 6, wherein in (a), a layer containing an element contained in the precursor and the substance X is formed as the substance X-containing layer.

8. The processing method of claim 1, wherein in (a), a layer capable of absorbing or adsorbing the substance X is formed in the first process container, and then the substance X is supplied into the first process container.

9. The processing method of claim 8, wherein in (a), a layer where the substance X is absorbed or adsorbed is formed as the substance X-containing layer.

10. The processing method of claim 1, wherein in (a), at least one selected from the group of a content of the substance X in the substance X-containing layer, a concentration of the substance X in the substance X-containing layer, a density of the substance X in the substance X-containing layer, and a thickness of the substance X-containing layer is different between one portion and another portion in the first process container.

11. The processing method of claim 1, wherein the substance X includes a hydrogen-and oxygen-containing substance.

12. The processing method of claim 1, wherein the first processing agent includes a fluorine-containing substance.

13. The processing method of claim 1, wherein the first processing agent includes a fluorine-and hydrogen-containing substance.

14. The processing method of claim 1, wherein in (c), an oxide formed on the surface of the substrate is removed.

15. The processing method of claim 14, wherein the oxide includes at least one selected from the group of a native oxide film and a chemical oxide film.

16. The processing method of claim 1, further comprising: (d) supplying a second processing agent to the substrate with the surface etched, thereby processing the substrate.

17. The processing method of claim 16, wherein in (d), a film-forming agent is supplied as the second processing agent to the substrate with the surface etched, thereby forming a film on the substrate with the surface etched.

18. The processing method of claim 16, wherein (d) is performed in a state where the substrate with the surface etched is loaded into a second process container.

19. The processing method of claim 18, further comprising: transporting the substrate with the surface etched from an inside of the first process container to an inside of the second process container in a non-atmospheric environment.

20. The processing method of claim 16, wherein (a) to (d) are performed a plurality of times, and there is a period during which (d) for an n-th time and at least one selected from the group of (a), (b), and (c) for an (n+1)-th time are performed in parallel.

21. A method of manufacturing a semiconductor device, comprising the processing method of claim 1.

22. A processing apparatus comprising:
a first process container into which a substrate is loaded;
a first processing agent supply system configured to supply a first processing agent to the substrate;
a transporter configured to load the substrate into the first process container; and
a controller configured to be capable of controlling the processing apparatus so as to perform a process including:
(a) preparing the first process container in which a substance X-containing layer is formed;
(b) loading the substrate into the first process container in which the substance X-containing layer is formed; and
(c) supplying the first processing agent to the substrate in the first process container in which the substance X-containing layer is formed, such that the first processing agent reacts with a substance X derived from the substance X-containing layer, thereby etching a surface of the substrate.

23. A non-transitory computer-readable recording medium storing a program that causes, by a computer, a processing apparatus to perform a process comprising:
(a) preparing a first process container in which a substance X-containing layer is formed;
(b) loading a substrate into the first process container in which the substance X-containing layer is formed; and
(c) supplying a first processing agent to the substrate in the first process container in which the substance X-containing layer is formed, such that the first processing agent reacts with a substance X derived from the substance X-containing layer, thereby etching a surface of the substrate.
